(19) United States
(12) Patent Application Publication
(10) Pub. No.: US 2022/0287455 A1
(43) Pub. Date: Sep. 15, 2022

(54) ROTATABLE DISPLAY SUPPORT

(71) Applicant: HAIDONG GU, Pomona, CA (US)

(72) Inventor: HAIDONG GU, Pomona, CA (US)

(21) Appl. No.: 17/198,244

(22) Filed: Mar. 11, 2021

(51) Int. Cl. A47B 23/06; F16M 13/02; A63B 71/06

(52) U.S. Cl. CPC A47B 23/06; F16M 13/022; A63B 71/0622; H05K 5/0204

(57) ABSTRACT

A rotatable display support includes a securing unit and a pivot unit. The securing unit is configured to assemble with an exercise machine, and the pivot unit is configured to assembled with a display. With configuration of the securing unit and the pivot unit, the user can rotate the display and operate functions of the display when using the exercise machine or doing other indoor exercise.

### BACKGROUND OF THE INVENTION

### 1. Field of the Invention

The present invention relates to a rotatable display support which is used to mount a display on an exercise machine, so that the display can be adjusted to rotate relative to the exercise machine.

### 2. Description of the Related Art

Many factors, such as poor weather, outdoor temperature and time, often limit people's willingness to exercise, but indoor exercise is less limited by climate change and temperature, so people are less likely to dispel willingness to exercise indoors and can choose suitable indoor exercise machines, thereby preventing from being affected by aforementioned factors. In recent years, common indoor exercise machines such as treadmills, sliding machines and exercise bikes are quite popular.

The person doing indoor exercise with the indoor exercise machine in familiar indoor environment usually likes to listen music or watch video with a personal mobile device or a tablet computers during exercise, so some manufacturers developed indoor exercise machines equipped with display, and the display can be used to play music or video through wired or wireless transmission, and show the adjustable values/information of the indoor exercise machine; alternatively, some manufacturers developed portable computer display devices in cooperation with indoor exercise machines. For example, People's Republic of China utility model patents No. CN206837347U and CN204996062U disclose indoor exercise machine equipped with a display device, and People's Republic of China utility model patent CN210896311U discloses a portable computer display device.

However, the aforementioned fixed-type display device can only provide the user to listen music or watch video at the location where the user is operating the exercise machine, and may be not practical for other indoor exercise such as warm-up before exercise, yoga, dumbbells, or skipping ropes. Furthermore, when not in use indoors, the aforementioned portable display device obviously occupies too much indoor space, so it is inconvenient for users having limited storage space.

### SUMMARY OF THE INVENTION

An objective to the present invention is to provide a rotatable display support which is used to mount a display on an exercise machine, so that a user can rotate the display and effectively use functions of the display when using the exercise machine or doing other indoor exercise.

In order to achieve the aforementioned objective and effect, the present invention provides a rotatable display support including a securing unit and a pivot unit. The securing unit includes a securing base and a securing shaft which are assembled with each other. The securing base is configured to assembled with an exercise machine. The pivot unit includes an adaptor base, a pivot base, an adjusting bolt and a display shaft set. A portion of the adaptor member is locked with the securing base, the adaptor base includes a pivot section extended toward a side of the securing base, the display shaft set is inserted through the pivot base to connect a display, and the adjusting bolt is inserted into and locked with the pivot base to make the pivot base movably clamp on a peripheral side of the pivot section.

### BRIEF DESCRIPTION OF THE DRAWINGS

The structure, operating principle and effects of the present invention will be described in detail by way of various embodiments which are illustrated in the accompanying drawings.

FIG. 1 is a perspective assembly view of a rotatable display support of the present invention.

FIG. 2 is a perspective exploded view of a rotatable display support of the present invention.

FIG. 3 is a perspective view of a rotatable display support of the present invention, before the rotatable display support is mounted on an exercise machine.

FIG. 4 is a perspective view of a rotatable display support of the present invention, after the rotatable display support is mounted on an exercise machine and before a display is mounted with the rotatable display support.

FIG. 5 is a perspective view showing that a display is mounted an exercise machine through a rotatable display support of the present invention.

FIGS. 6 and 7 are perspective views showing that a display is rotatable through a rotatable display support of the present invention.

FIG. 8 is a schematic cross-sectional view taken along VIII-VIII of FIG. 5.

FIG. 9 is a schematic view showing an operation of rotating an adjusting bolt to make a pivot lug member clamp a pivot section, according to the present invention.

FIG. 10 is a schematic view showing an operation of adjusting a tilt angle of a display, according to the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the, scope of the present invention in any way. Further modifications to the disclosed embodiments, as well as other embodiments, are also included within the scope of the appended claims.

These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts. As used herein, the singular forms “a”, “an” and “the” are intended to include the plural forms as well, unless the context clearly indicates otherwise. As used herein, the term “or” includes any and all combinations of one or more of the associated listed items.

It will be acknowledged that when an element or layer is referred to as being “on,” “connected to” another element or layer, it can be directly on, connected to the other element or layer, or intervening elements or layers may be present. In contrast, when an element is referred to as being “directly on,” “directly connected to” another element or layer, there are no intervening elements or layers present.

In addition, unless explicitly described to the contrary, the words “comprise” and “include”, and variations such as “comprises”, “comprising”, “includes”, or “including”, will be acknowledged to imply the inclusion of stated elements but not the exclusion of any other elements.

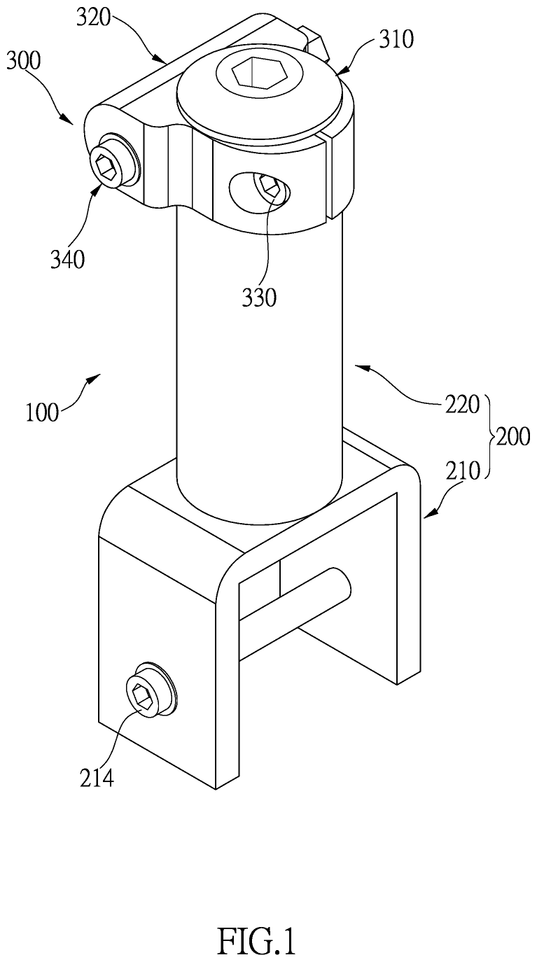

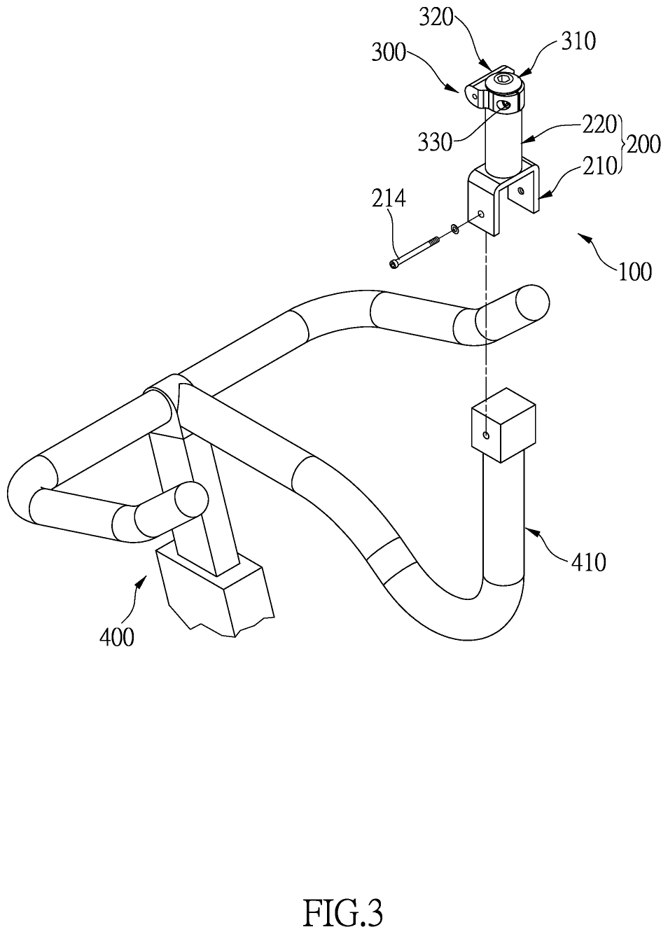

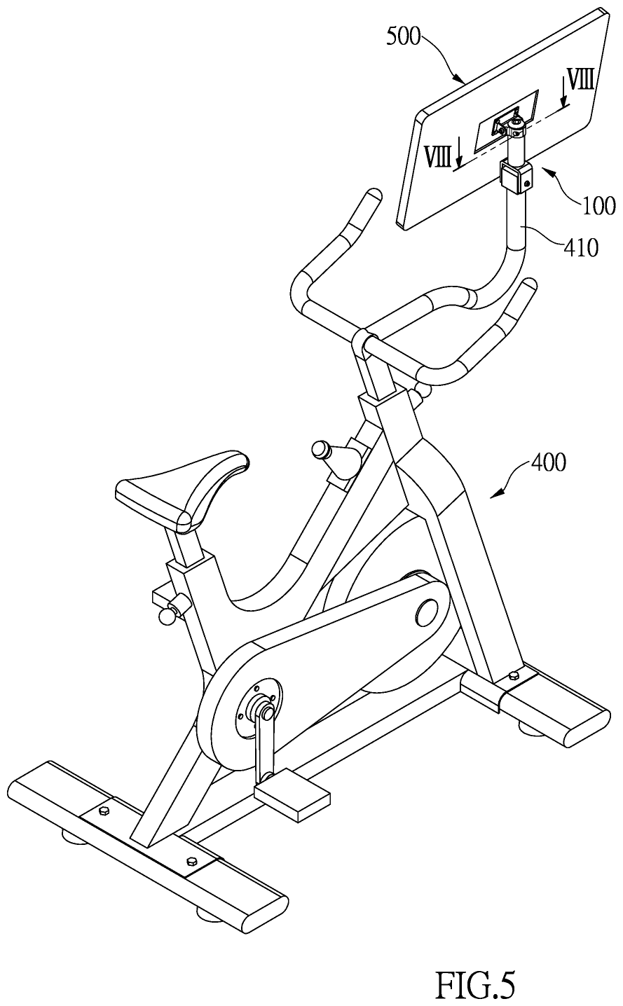

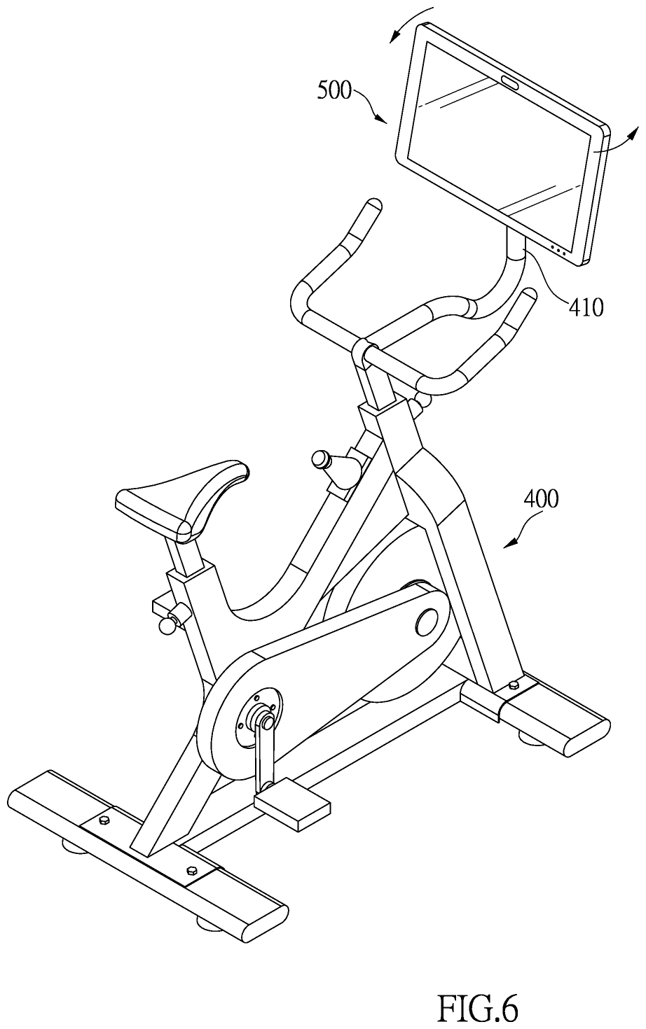

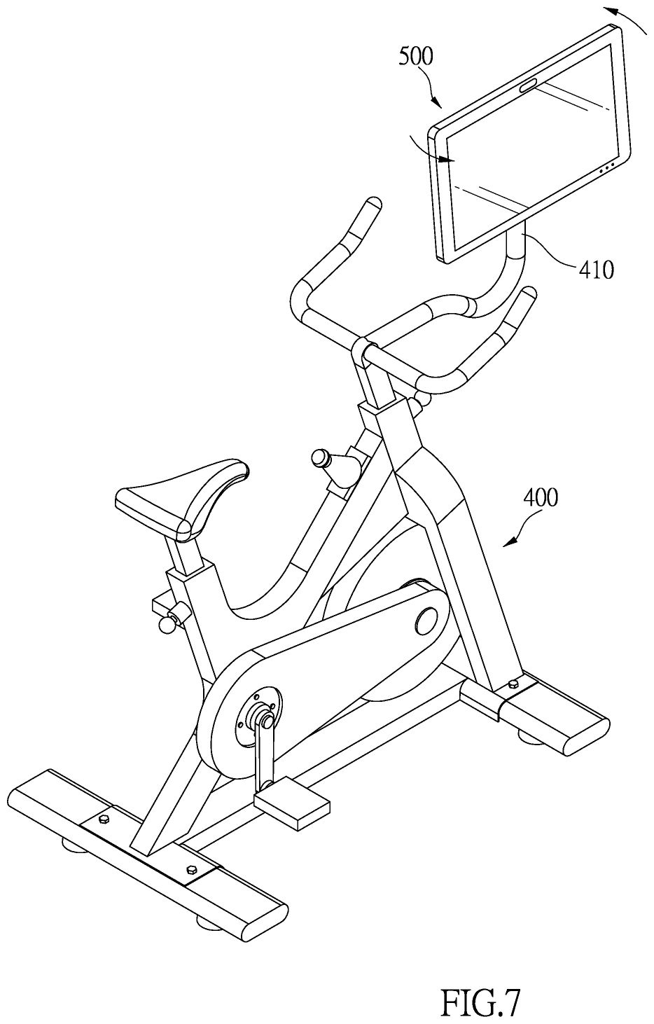

Please refer to FIGS. 1 to 7. As shown in FIGS. 1 to 7, a rotatable display support 100 includes a securing unit 200 and a pivot unit 300. The securing unit 200 includes a securing base 210 and a securing shaft 220 which are assembled with each other, and the securing base 210 is configured to assemble with an exercise machine 400. The pivot unit 300 includes an adaptor base 310, a pivot base 320, an adjusting bolt 330 and a display shaft set 340. A portion of the adaptor base 310 is locked with the securing base 210, and the adaptor member 310 includes a pivot section 311 extended toward a side of the securing base 210. The display shaft set 340 is inserted into the pivot base 320 to connect with a display 500. The adjusting bolt 330 is inserted into and locked with the pivot base 320, so as to make the pivot base 320 movably clamp a peripheral side of the pivot section 311.

In an embodiment, the exercise machine 400 can be, for example, an exercise bike and the rotatable display support 100 is mounted on a distal end of an extension rod 410 of the exercise bike, so that the rotatable display support 100 is disposed on a front end of the exercise bike, and a portion of the extension rod 410 is in a bent-and-extended shape. The display 500 can, for example, play a multimedia file by connecting to internet or a personal mobile device in a wireless/wired manner. The display 500 can be controlled by a touch operation, a button operation, or a remote-control operation. Furthermore, in other embodiment, the rotatable display support 100 of the present invention can be adapted to a treadmill or a sliding machine.

After the display 500 is mounted on the exercise machine 400 through the rotatable display support of the present invention, the user riding the exercise machine 400 can operate the display 500 with a display range in a direction from the front side to rear side of the exercise machine 400; furthermore, the user just needs to apply force on two sides of the display 500 to rotate the display 500 with respect to the pivot section 311 about the pivot base 320 so that the display range of the display 500 can be toward a circumferential side of the exercise machine 400, so that the user can watch video or listen music while doing other indoor exercise (such as yoga or dumbbell training) at the position other than the exercise machine 400, in this case, the exercise machine 400 can serve as a floor-standing frame to support the display 500 off the ground for use. As a result, the rotatable display support of the present invention can improve the using effect of the exercise machine 400.

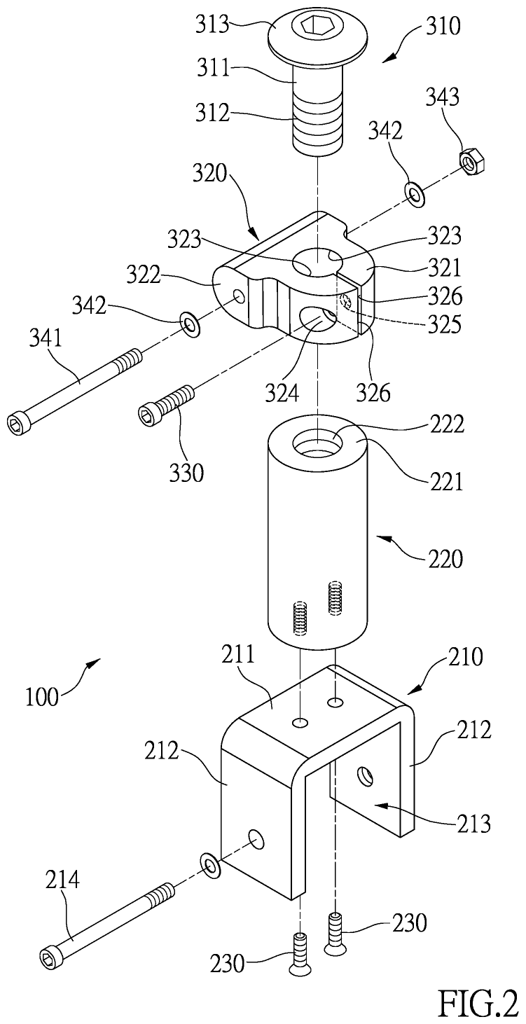

The detailed features and assembly relationships of components of the rotatable display support of the present invention will be illustrated in detail in following paragraphs. Please refer to FIGS. 2 to 5. The securing base 210 includes a support section 211 and a pair of lateral lug members 212. Each of the pair of lateral lug members 212 has an end integrally connected to one of two ends of the support section 211, so that an exercise groove 213 can be formed and surrounded between the pair of lateral lug members 212 and the support section 211. Furthermore, an exercise bolt 214 can be inserted into the exercise machine 400 and also inserted through and locked with the pair of lateral lug members 212, so that a portion of the exercise machines 400 can be accommodated in the exercise groove 213. After the extension rod 410 of the exercise machine 400 can be accommodated in the exercise groove 213, and the exercise bolt 214 can be inserted into the extension rod 410 and screwed with the lateral lug member 212, so that the user can mount the rotatable display support 100 with the exercise machine 400 conveniently.

Furthermore, a plurality of screws 230 can be inserted into the support section 211 and locked with a lower end of the securing shaft. The securing base 210 and the securing shaft 220 can be assembled to form the securing, unit 200 by a manner of using the plurality of screws 230 to assemble the two pieces of members, so the rotatable display support of the present invention is easy to process, manufacture and assemble in production.

Two ends of the pivot section 311 are connected to the connection section 312 and the constraining cone section 313, respectively, and the securing shaft 220 has a support surface 221 formed on an upper end thereof and in contact with a lower surface of the pivot base 320. The support surface 221 has an adaptor hole 222 formed therein, and the connection section 312 of the adaptor member 310 is locked in the adaptor hole 222, and the constraining cone section 313 is disposed on a top of the pivot base 320 and configured to prevent the pivot base 320 from being separated from the pivot section 311. The support surface 221 is in contact with a bottom surface of the pivot base 320, so that a weight of the display 500 can be distributed on the support surface 221.

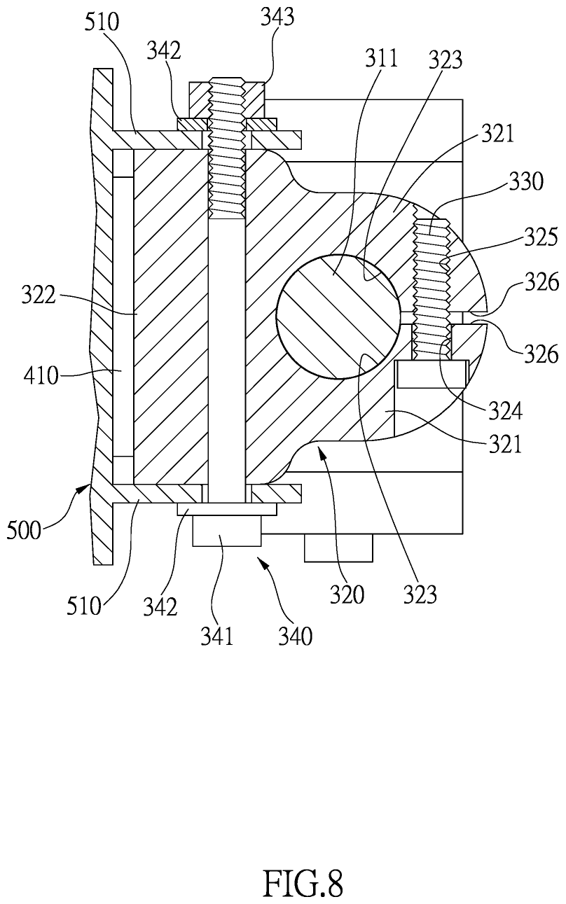

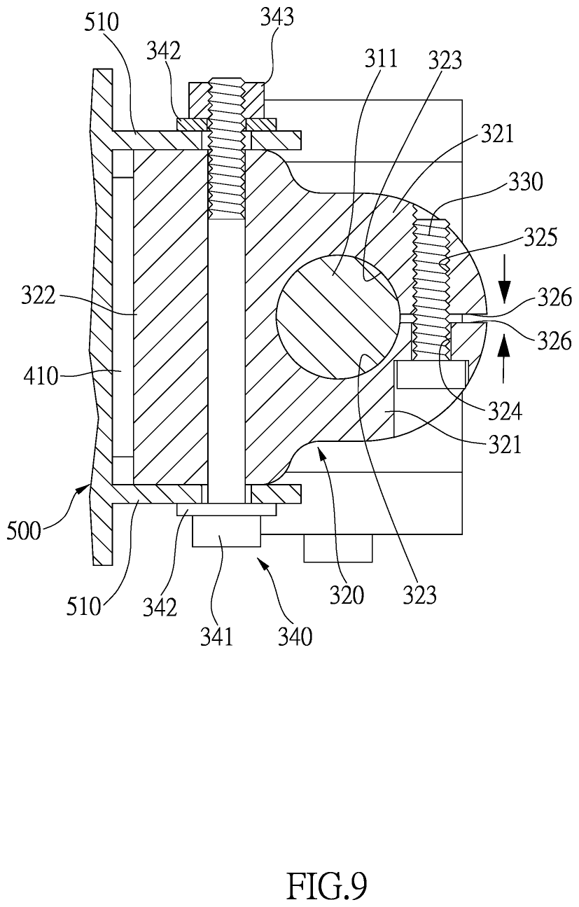

Please refer to FIGS. 2, 4, 8 and 9. The pivot base 320 includes a pair of pivot lug members 321 and a securing lug member 322. Each pivot lug member has an arc surface 323 in contact with a peripheral side of the pivot section 311. The pair of pivot lug members 321 have a pass hole 324 and a locking hole 325, respectively, and the adjusting bolt 330 is inserted into the pass hole 324 and locked in the locking hole 325. Each pivot lug member 321 has an inner surface 326 adjacent to the arc surface 323, and the inner surfaces 326 of the pair of pivot lug members 321 face to each other; when the adjusting bolt 330 is inserted into the pass hole 324 and locked in the locking hole 325, the inner surfaces 326 of the pair of pivot lug members 321 are not in contact with each other. In the present invention, positively rotating the adjusting bolt 330 to screw with the locking hole 325 makes the arc surfaces 323 of the pair of pivot lug members 321 tightly clamp the pivot section 311 from a releasing statue, and reversely rotating the adjusting bolt 330 make the arc surfaces 323 of the pair of pivot lug members 321 release from the status of tightly clamping the pivot section 311, so that the user can control the difficulty in rotating the display 500 with respect to the pivot section 311, even control the display 500 in the completely-locked status.

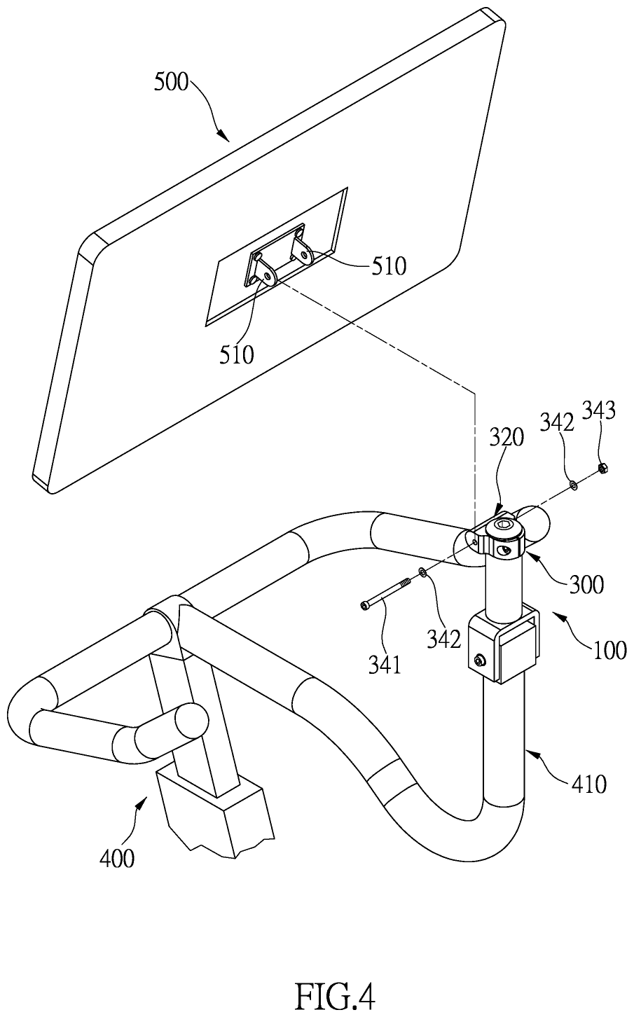

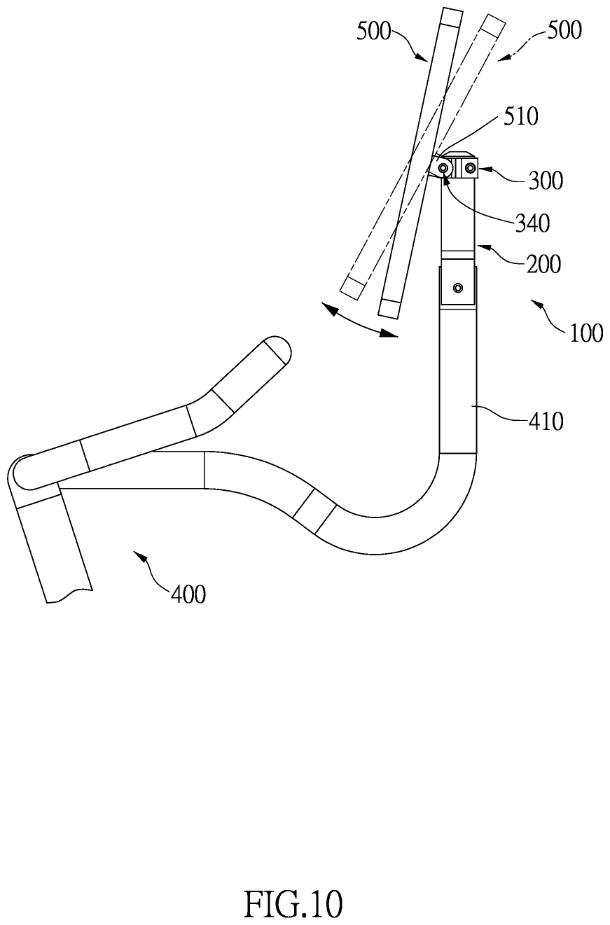

Please refer to FIGS. 4, 8 to 10, which shows an operation of using the rotatable display support 100 to mount the display 500. The display shaft set 340 includes a display bolt 341, a pair of washers 342 and a display nut 343. The pair of washers 342 are disposed on two opposite sides of the securing lug members 312, respectively. The display bolt 341 is inserted into the pair of washers 342 and the securing lug member 322 to screw with the display nut 343. The display 500 includes a pair of display lug members 510 disposed on a back side thereof and arranged in interval, and the display bolt 341 is inserted into the pair of display lug members 510, and the pair of display lug members 510 are located on inner sides of the pair of washers 342, respectively, and the display lug member 510 is abutted between the washer 342 and an outer surface of the securing lug member 322, so that the display 500 is swingable upwardly and downwardly with respect to the display bolt 341 through the pair of display lug members 510, thereby adjusting the tilt angle of the display 500 for watching. As shown in FIG. 10, a dashed line indicates an initial position of the display 500 and a solid line indicates an adjusted position of the display 500.

The present invention disclosed herein has been described by means of specific embodiments. However numerous modifications, variations and enhancements can be made thereto by those skilled in the art without departing from the spirit and scope of the disclosure set forth in the claims.

What is claimed is:

1. A rotatable display support, comprising:
a securing unit comprising a securing base and a securing shaft which are assembled with each other, wherein the securing base is configured to assembled with an exercise machine; and
a pivot unit comprising an adaptor base, a pivot base, an adjusting bolt and a display shaft set, wherein a portion of the adaptor member is locked with the securing base, the adaptor base comprises a pivot section extended toward a side of the securing base, the display shaft set is inserted through the pivot base to connect a display, and the adjusting bolt is inserted into and locked with the pivot base to make the pivot base movably clamp on a peripheral side of the pivot section.

2. The rotatable display support according to claim 1, wherein the securing base comprises a support section and a pair of lateral lug members, and each of the pair of the lateral lug members has an end integrally connected to one of two ends of the support section, so as to form an exercise groove between the lateral lug members and the support section, wherein an exercise bolt is inserted into the exercise machine to lock with the pair of lateral lug members, so that a portion of the exercise machine is accommodated in the exercise groove;
wherein a plurality of lower screws are inserted into the support section to secure with a lower end of the securing shaft.

3. The rotatable display support according to claim 1, wherein the adaptor member comprises a connection section and a constraining cone section, and two ends of the pivot section are connected to the connection section and the constraining cone section, respectively, the securing shaft has a support surface formed on an upper end and in contact with a lower surface of the pivot base, the support surface has an adaptor hole formed therein, the connection section of the adaptor member is locked with the adaptor hole, and the constraining cone section is disposed on a top of the pivot base and configured to prevent the pivot base from being separated from the pivot section.

4. The rotatable display support according to claim 1, wherein the pivot base comprises a pair of pivot lug members and a securing lug member, and each of the pair of pivot lug members has an arc surface in contact with a peripheral side of the pivot section, the pair of pivot lug members have a pass hole and a locking hole formed thereon, respectively, and the adjusting bolt is insert into the pass hole and locked with the locking hole.

5. The rotatable display support according to claim 4, wherein each of the pair of pivot lug members has an inner surface disposed adjacent to the arc surface, and the inner surfaces of the pair of pivot lug members face to each other, and when the adjusting bolt is inserted into the pass hole and locked with the locking hole, the inner surfaces of the pair of pivot lug members are not in contact with each other.

6. The rotatable display support according to claim 4, wherein the display shaft set comprises a display bolt, a pair of washers, and a display nut, the pair of washers are disposed on two opposite sides of the securing lug member, respectively, and the display bolt is inserted through the pair of washers and the securing ling member to screw with the display nut.
